(19) United States
(12) Patent Application Publication
(10) Pub. No.: US 2016/0126268 A1
(43) Pub. Date: May 5, 2016

(54) SEMICONDUCTOR DEVICE, SOLID-STATE IMAGING DEVICE AND CAMERA MODULE

(71) Applicant: Kabushiki Kaisha Toshiba, Minato-ku (JP)

(72) Inventors: Hiroki INOUE, Kitakami (JP); Hiroshi Iizuka, Kitakami (JP)

(73) Assignee: Kabushiki Kaisha Toshiba, Minato-ku (JP)

(21) Appl. No.: 14/843,517

(22) Filed: Sep. 2, 2015

(30) Foreign Application Priority Data
Oct. 30, 2014 (JP) 2014-221326

(51) Int. Cl. H01L 27/146; H04N 5/369; H04N 5/225

(52) U.S. Cl. CPC H01L 27/14603; H04N 5/2254; H04N 5/369; H01L 27/14636; H01L 27/14627

(57) ABSTRACT

Certain embodiments provide a solid-state imaging device including: a semiconductor substrate having a top surface on which a light receiving section that receives light is provided, the semiconductor substrate having a through hole which is provided in a part of the semiconductor substrate; an electrode pad provided on the top surface side of the semiconductor substrate including an area right above the through hole to be in contact with the first wiring, the electrode pad having a slit between the area right above the through hole and the first wiring; an insulating film provided on a side surface of the through hole; and a second wiring provided on the insulating film to be in contact with the electrode pad.

### CROSS REFERENCE TO RELATED APPLICATIONS

This application is based upon and claims the benefit of priority from the prior Japanese Patent Application No. 2014-221326 filed in Japan on Oct. 30, 2014; the entire contents of which are incorporated herein by reference.

### FIELD

Embodiments described herein relate generally to a semiconductor device, a solid-state imaging device and a camera module.

### BACKGROUND

A camera module of a chip scale camera module (the CSCM) type (hereinafter, referred to as the CSCM) has been known as an example of a small camera module to be mounted to an electronic device such as a mobile phone. The CSCM is configured by fixing a lens holder including a lens or the like onto a solid-state imaging device.

The solid-state imaging device to be applied to the CSCM is configured by fixing a glass substrate on a thin semiconductor substrate of which a top surface is provided with a light receiving section that receives light by an adhesive. The glass substrate is used as a supporting substrate for forming the thin semiconductor substrate including the light receiving section.

In the solid-state imaging device to be applied to the CSCM, an electrode pad to be electrically connected to the light receiving section is provided on the top surface of the semiconductor substrate around the light receiving section. A through hole is provided in the semiconductor substrate right below this electrode pad. Thus, a wiring is formed on an area from a side surface of the through hole to a rear surface of the semiconductor substrate so as to be electrically connected to the electrode pad via an insulating film. In addition, a solder ball serving as an external electrode is formed on the wiring on the rear surface of the semiconductor substrate.

In such a solid-state imaging device, an electrical signal generated by receiving light in the light receiving section is propagated to the solder ball via the electrode pad and the wiring, and is output to outside of the solid-state imaging device via the solder ball.

### BRIEF DESCRIPTION OF THE DRAWINGS

FIG. 1A is a vertical cross-sectional view schematically illustrating a solid-state imaging device according to an embodiment,

FIG. 1B is a vertical cross-sectional view schematically illustrating a camera module to which the solid-state imaging device illustrated in FIG. 1A is applied,

FIG. 2 is an enlarged view illustrating a main part surrounded by a dotted line X of the solid-state imaging device illustrated in FIG. 1A,

FIG. 3 is an enlarged top view illustrating a part of a first wiring pattern and an electrode pad,

FIG. 4 is a diagram for describing a manufacturing method of the solid-state imaging device according to the embodiment, and an enlarged view of a main section corresponding to FIG. 2,

FIG. 5 is a diagram for describing the solid-state imaging device manufacturing method according to the embodiment, and an enlarged view of a main section corresponding to FIG. 2,

FIG. 6 is a diagram for describing the solid-state imaging device manufacturing method according to the embodiment, and an enlarged view of a main section corresponding to FIG. 2,

FIG. 7 is a diagram for describing the solid-state imaging device manufacturing method according to the embodiment, and an enlarged view of a main section corresponding to FIG. 2,

FIG. 8 is a diagram for describing the solid-state imaging device manufacturing method according to the embodiment, and an enlarged view of a main section corresponding to FIG. 2,

FIG. 9 is a diagram for describing the solid-state imaging device manufacturing method according to the embodiment, and an enlarged view of a main section corresponding to FIG. 2,

FIG. 10 is a diagram for describing the solid-state imaging device manufacturing method according to the embodiment, and an enlarged view of a main section corresponding to FIG. 2,

FIG. 11 is a diagram for describing the solid-state imaging device manufacturing method according to the embodiment, and an enlarged view of a main section corresponding to FIG. 2,

FIG. 12 is a diagram for describing the solid-state imaging device manufacturing method according to the embodiment, and an enlarged view of a main section corresponding to FIG. 2,

FIG. 13 is a top view illustrating an electrode pad of a first comparative example, and corresponding to FIG. 3,

FIG. 14 is a top view illustrating an electrode pad of a second comparative example, and corresponding to FIG. 3,

FIG. 15 is a diagram for describing a measurement position of stress in simulation,

FIG. 16 is a graph illustrating a calculation result of the stress applied to a semiconductor substrate right below each measurement position in a case where each of the electrode pads of the first comparative example and the second comparative example is formed,

FIG. 17 is a top view illustrating an electrode pad of a first embodiment, and corresponding to FIG. 3,

FIG. 18 is a top view illustrating an electrode pad of a second embodiment, and corresponding to FIG. 3,

FIG. 19 is a graph illustrating the calculation result of the stress applied to the semiconductor substrate right below each measurement position in a case where each of the electrode pads of the first embodiment, the second embodiment, and the second comparative example is formed,

FIG. 20 is a top view for describing a more preferable shape of a slit that corresponds to FIG. 3,

FIG. 21 is a top view illustrating an electrode pad of a third embodiment, and corresponding to FIG. 3,

FIG. 22 is a top view illustrating an electrode pad of a fourth example, and corresponding to FIG. 3,

FIG. 23 is a graph illustrating the calculation result of the stress applied to the semiconductor substrate right below each measurement position in a case where each of the electrode pads of the third embodiment, the fourth embodiment, and the second comparative example is formed, and

FIG. 24 is a top view illustrating an electrode pad according to a modified example of the embodiment, and corresponding to FIG. 3.

### DESCRIPTION OF THE EMBODIMENTS

Certain embodiments provide a solid-state imaging device including: a semiconductor substrate having a top surface on which a light receiving section that receives light is provided, the semiconductor substrate having a through hole which is provided in a part of the semiconductor substrate; an electrode pad provided on the top surface side of the semiconductor substrate including an area right above the through hole to be in contact with the first wiring, the electrode pad having a slit between the area right above the through hole and the first wiring; an insulating film provided on a side surface of the through hole; and a second wiring provided on the insulating film to be in contact with the electrode pad.

Certain embodiments provide a camera module including a solid-state imaging device, and a lens holder having a lens which is included inside the lens holder. The solid-state imaging device is provided with: a semiconductor substrate having a top surface on which a light receiving section that receives light condensed by the lens is provided, the semiconductor substrate having a through hole which is provided in a part of the semiconductor substrate; an electrode pad provided on the top surface side of the semiconductor substrate including an area right above the through hole to be in contact with the first wiring, the electrode pad having a slit between the area right above the through hole and the first wiring; an insulating film provided on a side surface of the through hole; and a second wiring provided on the insulating film to be in contact with the electrode pad. The lens holder is provided on the top surface of the semiconductor substrate.

Certain embodiments provide a semiconductor device including: a first wiring provided on a top surface side of a semiconductor substrate having a through hole; an electrode pad provided on the top surface side of the semiconductor substrate including an area right above the through hole to be in contact with the first wiring, the electrode pad having a slit between the area right above the through hole and the first wiring; an insulating film provided on a side surface of the through hole; and a second wiring provided on the insulating film to be in contact with the electrode pad.

The present embodiment is a semiconductor device in which a first wiring pattern and an electrode pad to be connected to the first wiring pattern are provided on a top surface of a semiconductor substrate with a first insulating film interposed therebetween, and further a through hole is formed in the semiconductor substrate right below the electrode pad, and a second wiring pattern is provided on a second insulating film on a side surface of the through hole so as to be connected to the electrode pad. In the semiconductor device, a slit is provided in the electrode pad. It is possible to suppress generation of a crack in the semiconductor substrate around the through hole by providing the slit, and thus, it is possible to manufacture the semiconductor device with a high yield. Hereinafter, a description will be made in detail regarding a solid-state imaging device as an example of a semiconductor device according to this embodiment and a camera module to which the solid-state imaging device is applied with reference to the drawings.

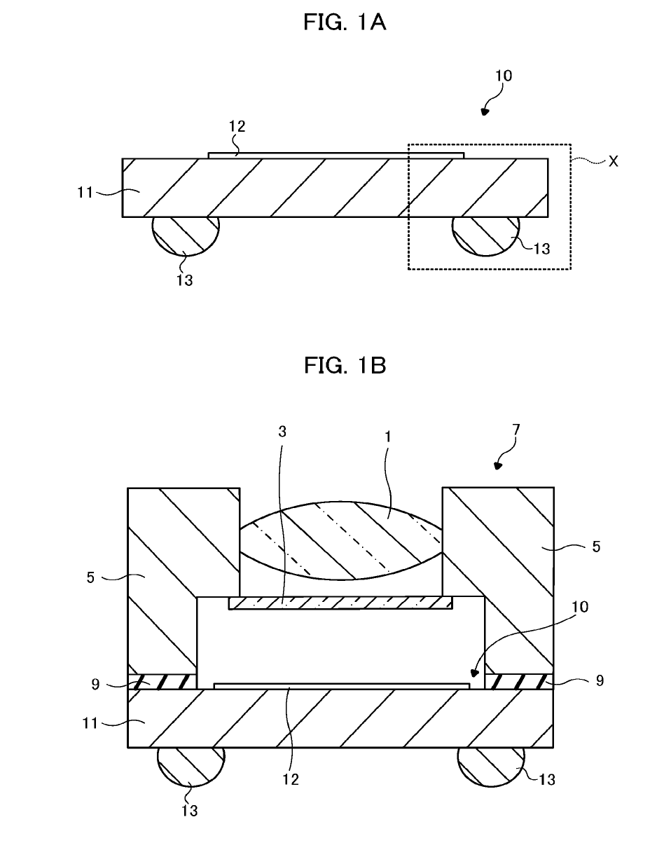

FIG. 1A is a vertical cross-sectional view schematically illustrating the solid-state imaging device according to the embodiment. As illustrated in FIG. 1B, a solid-state imaging device 10 illustrated in FIG. 1A is a solid-state imaging device that is applied to a camera module 7 of a chip scale camera module (CSCM) type, which has a lens holder 5 including a lens 1 and an infrared cutoff filter 3 inside thereof, and is not provided with a supporting substrate such as a glass substrate.

Incidentally, as illustrated in FIG. 1B, the lens holder 5 is not provided on the supporting substrate such as the glass substrate like a conventional camera module, but is provided on a top surface of a semiconductor substrate 11 of the solid-state imaging device 10 with an adhesive 9 interposed therebetween. Accordingly, as will be described later, a sensor chip 12 of the solid-state imaging device 10 is capable of directly receiving light to be condensed by the lens 1 without intervention of the supporting substrate such as the glass substrate. As a result, it is possible to provide the camera module 7 with high sensitivity.

In the solid-state imaging device 10 illustrated in FIG. 1A, for example, the sensor chip 12 is provided on the top surface of the thin semiconductor substrate 11 made using silicon. The sensor chip 12 is a light receiving section that directly receives the light to be condensed by the lens 1 (FIG. 1B) without the intervention of the supporting substrate such as the glass substrate, and outputs an electrical signal depending on the amount of the received light.

A solder ball 13 serving as an external electrode is mounted onto a rear surface of the semiconductor substrate 11. The solder ball 13 is electrically connected to the sensor chip 12 provided on the top surface of the semiconductor substrate 11 through a desired structure to be described later. Accordingly, the electrical signal, generated by the sensor chip 12 by receiving the light, can be output to outside of the solid-state imaging device 10 via the solder ball 13.

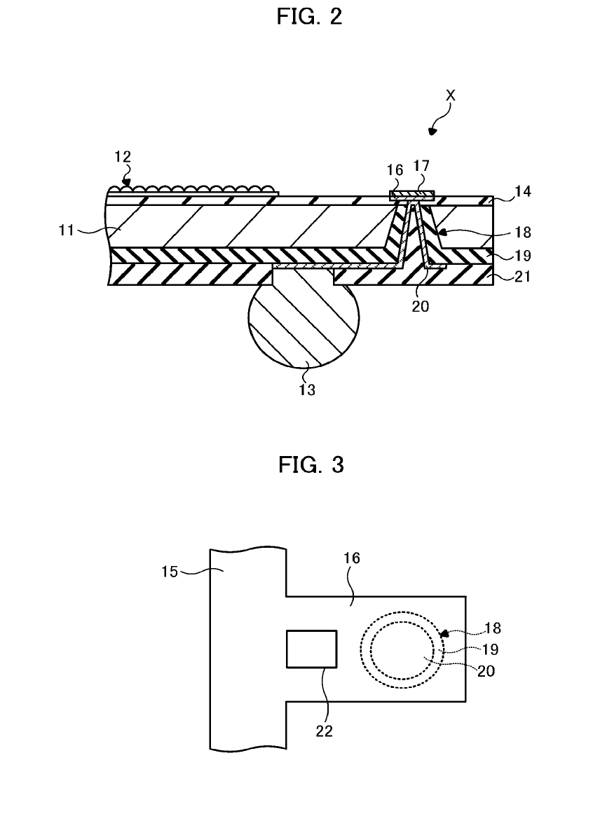

FIG. 2 is an enlarged view illustrating a main part surrounded by a dotted line X of the solid-state imaging device 10 illustrated in FIG. 1A. Hereinafter, a description will be made regarding the desired structure for causing the sensor chip 12 and the solder ball 13 to be electrically connected to each other with reference to FIG. 2.

A first insulating film 14, made of SiO₂, for example, is formed on the top surface of the semiconductor substrate 11. The sensor chip 12 is provided on a top surface of the first insulating film 14.

A first wiring pattern 15 (FIG. 3 which will be described later) and an electrode pad 16 to be connected to the first wiring pattern 15 are provided, using aluminum, for example, on the top surface of the first insulating film 14 while being on the top surface side of the semiconductor substrate 11. The first wiring pattern 15 is electrically connected to the sensor chip 12, for example. An insulating protective film 17 made of SiN, for example, is provided on the top surface of the first wiring pattern 15 and a top surface of the electrode pad 16.

A through hole 18 is provided in the semiconductor substrate 11 right below the electrode pad 16. The through hole 18 is provided to penetrate through each of the semiconductor substrate 11 right below the electrode pad 16 and the first insulating film 14. Accordingly, a rear surface of the electrode pad 16 is exposed from the through hole 18.

A second insulating film 19, made of SiO₂, for example, is formed on a side surface of the through hole 18 and on the rear surface of the semiconductor substrate 11. The second insulating film 19 is a CVD film that is formed by a CVD method.

A second wiring pattern 20 to be formed using aluminum, for example, is formed on the rear surface side of the semiconductor substrate 11, and inside the through hole 18. The second wiring pattern 20 is formed on the second insulating film 19. The second wiring pattern 20 is provided to be in contact with the rear surface of the electrode pad 16 which is exposed from the through hole 18. In this manner, the second wiring pattern 20 is electrically connected to the electrode pad 16.

A solder resist film 21 serving as a protective film is formed on the second insulating film 19 which includes the second wiring pattern 20. The solder resist film 21 is provided on the second insulating film 19 so as to fill the through hole 18. The solder resist film 21 has an opening portion that exposes a part of the second wiring pattern 20.

The solder ball 13 serving as the external electrode is formed on the second wiring pattern 20 exposed through the opening portion of the solder resist film 21 so as to be in contact with the second wiring pattern 20. In other words, the solder ball is formed so as to be electrically connected to the second wiring pattern 20.

According to the structure described above, the sensor chip 12 is electrically connected to the solder ball 13 via the first wiring pattern 15, the electrode pad 16 and the second wiring pattern 20.

A description will be made further in detail regarding the first wiring pattern 15 and the electrode pad 16 with reference to FIG. 3. FIG. 3 is an enlarged top view illustrating a part of the first wiring pattern 15 and the electrode pad 16. As illustrated in FIG. 3, the electrode pad 16 is a pattern having substantially a rectangular shape, and is provided to be in contact with the first wiring pattern 15 so as to protrude in a convex shape in a direction perpendicular with respect to a longitudinal direction of the first wiring pattern 15. The electrode pad 16 is provided in a predetermined area on the top surface of the semiconductor substrate 11 which includes an area right above the through hole 18 (the dotted line in FIG. 3).

A slit 22 is provided in some area of the electrode pad 16. The slit 22 is provided in order to suppress generation of a crack in the semiconductor substrate 11 around the through hole 18 due to heat at the time of forming the second insulating film 19.

Incidentally, as will be described later in detail, it has become apparent that the crack is easily generated in a portion closer the first wiring pattern 15 in the semiconductor substrate around the through hole 18, through studies conducted by the inventor or the like. Accordingly, the slit 22 is provided in the vicinity of the portion in which the crack is easily generated, that is, between an area corresponding to the through hole, which is the area right above the through hole 18 in the electrode pad 16, and the first wiring pattern 15.

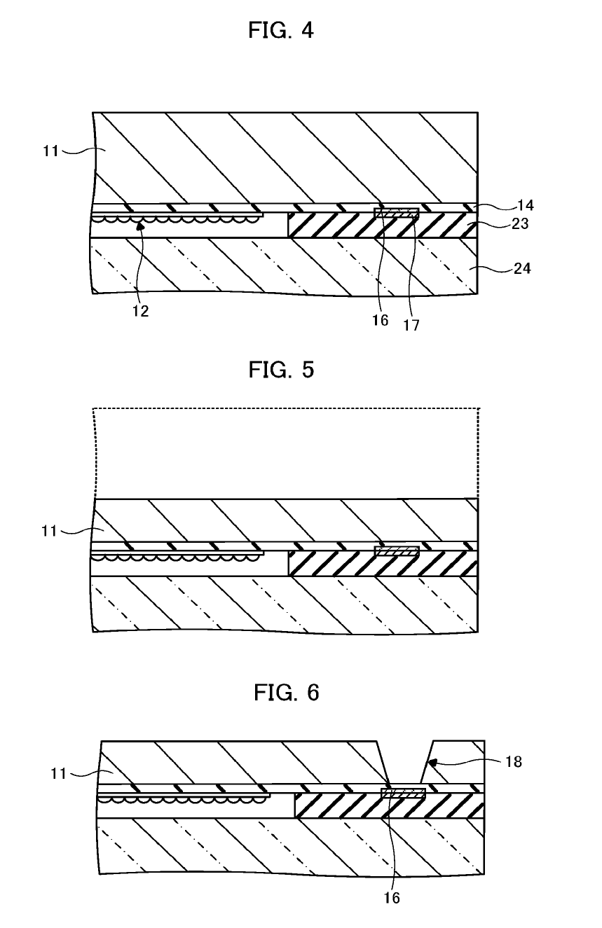

Next, a description will be made regarding a manufacturing method of the solid-state imaging device 10 configured as above with reference to FIG. 4 to FIG. 12. FIG. 4 to FIG. 12 are, respectively, diagrams for describing the manufacturing method of the solid-state imaging device 10 according to the embodiment, and enlarged views of the main section corresponding to FIG. 2.

Each drawing of FIG. 4 to FIG. 12 illustrates the main section of the solid-state imaging device illustrated in FIG. 2 in a vertically inverted manner. Accordingly, in a case where a top surface is referred, it means a lower surface of FIG. 4 to FIG. 12, and in a case where a rear surface is referred, it means a top surface of FIG. 4 to FIG. 12 in the description of the manufacturing method hereinafter.

First, as illustrated in FIG. 4, the sensor chip 12 is formed on the top surface of the semiconductor substrate 11 with the first insulating film 14 interposed therebetween. In addition, the first wiring pattern 15 (not illustrated) and the electrode pad 16 having the slit 22 are formed on the top surface of the first insulating film 14. Thereafter, the first wiring pattern 15 and the electrode pad 16 are covered by the protective film 17.

Subsequently, an adhesive 23 is applied to the top surface of the semiconductor substrate 11 around the sensor chip 12, and a glass substrate 24 is bonded to the top surface of the semiconductor substrate 11 using the adhesive 23. The glass substrate 24 is a supporting substrate when the semiconductor substrate 11 is made thinner and the through hole 18 is formed later.

In the related art, it is not assumed that the glass substrate is later peeled off from the semiconductor substrate, and thus, plasticity is not required as the adhesive to fix the glass substrate to the semiconductor substrate. However, in the present embodiment, an adhesive having a performance of peeling off the glass substrate 24 from the semiconductor substrate 11 eventually, for example, a thermoplastic or an optical plastic adhesive, or the like, is used as the adhesive 23 in order to peel off the glass substrate 24 from the semiconductor substrate 11 later.

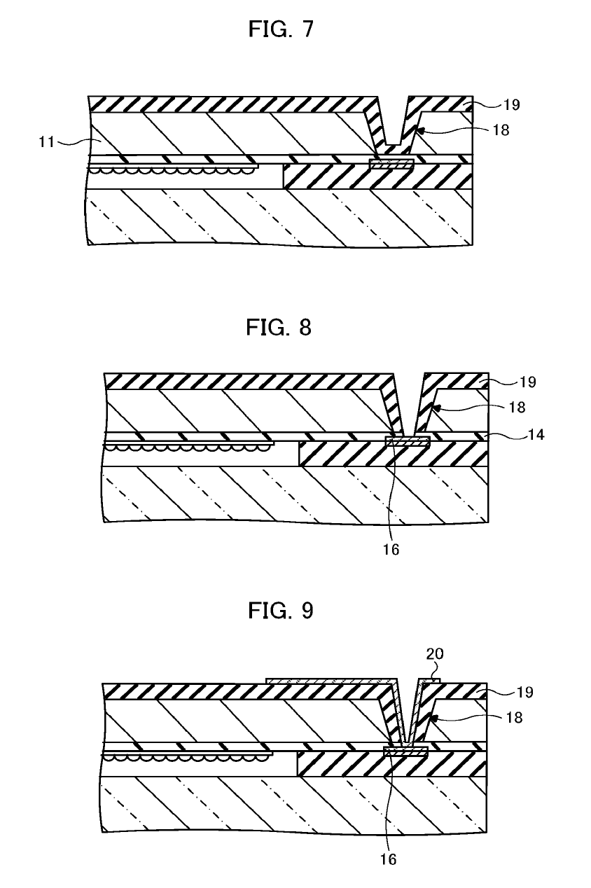

Next, the semiconductor substrate 11 is thinned by polishing the semiconductor substrate 11 from the rear surface side or the like (FIG. 5), and the through hole 18 having a tapered shape, for example, is formed so as to penetrate through the semiconductor substrate 11 right below the electrode pad 16 (right above in FIG. 6) (FIG. 6). Thereafter, the second insulating film 19 is formed using the CVD method on the rear surface of the semiconductor substrate 11 and on the side surface of the through hole 18 (FIG. 7).

Next, a part of the second insulating film 19 and the first insulating film 14 inside the through hole 18 is removed by etching so as to expose a part of the electrode pad 16 (FIG. 8). Thereafter, the second wiring pattern 20 is formed on the rear surface of the semiconductor substrate 11, and on the second insulating film 19 formed inside the through hole 18 so as to be in contact with the electrode pad 16 (FIG. 9).

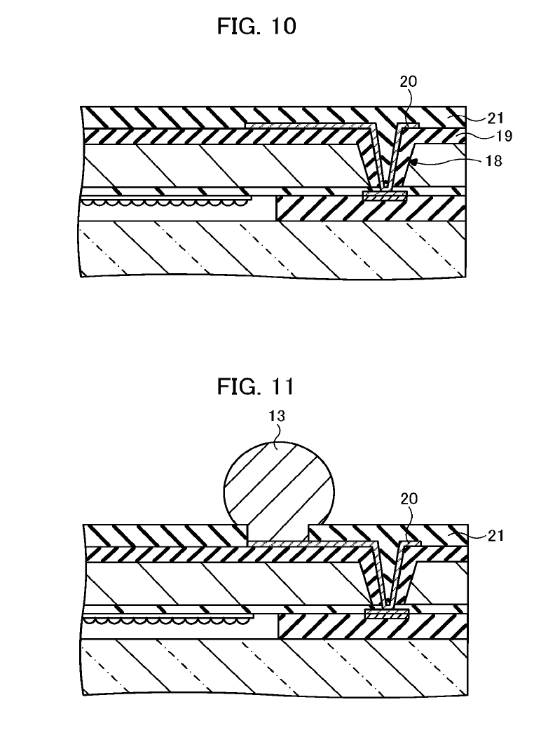

Next, the solder resist film 21 is formed on the second insulating film 19 which includes the second wiring pattern 20 so as to fill the through hole 18 (FIG. 10). Thus, the opening portion that exposes a part of the second wiring pattern 20 is formed in the solder resist film 21, and the solder ball 13 is formed so as to be in contact with the second wiring pattern 20 exposed through the opening portion (FIG. 11).

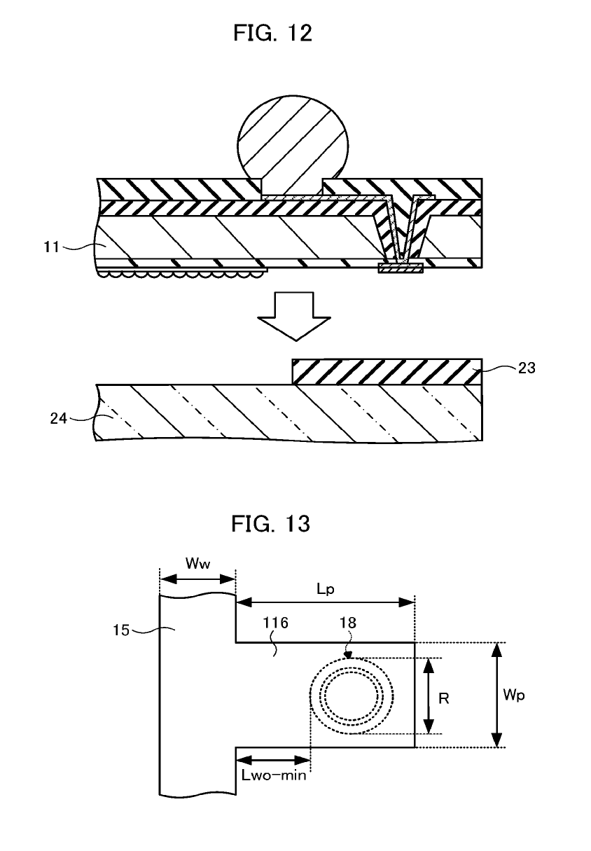

Finally, as illustrated in FIG. 12, the glass substrate 24 is peeled off from the semiconductor substrate 11 by softening the adhesive 23 interposed between the semiconductor substrate 11 and the glass substrate 24 or the like. In this manner, it is possible to manufacture the solid-state imaging device 10 illustrated in FIG. 1 and FIG. 2.

In the solid-state imaging device 10 manufactured in such a manner, the slit 22 is provided in the electrode pad 16 as illustrated in FIG. 3. Accordingly, the stress, which is applied to the semiconductor substrate 11 around the through hole 18 due to the heat generated in the step (CVD step) of forming the second insulating film 19 illustrated in FIG. 7, is relieved, and thus, it is possible to suppress the generation of the crack. Such an effect according to the slit 22 was found out through the following study conducted by the inventor of the present application or the like. Hereinafter, a description will be made regarding simulation conducted by the inventor of the present application or the like.

The inventor of the present application or the like conducted studies through the simulation regarding the stress applied to the semiconductor substrate 11 around the through hole 18 due to a heat process of the CVD step or the like, for example, illustrated in FIG. 7.

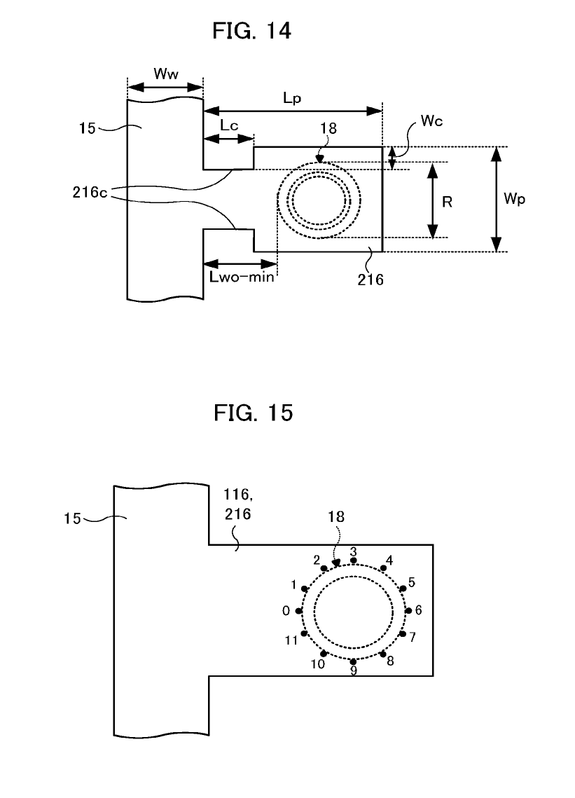

First, simulation was conducted regarding a case where the electrode pad having a shape illustrated in each of FIG. 13 and FIG. 14 was formed. FIG. 13 is a top view illustrating the electrode pad of a first comparative example, and corresponding to FIG. 3, and FIG. 14 is a top view illustrating an electrode pad of a second comparative example and corresponding to FIG. 3. Incidentally, in each drawing of FIG. 13 and FIG. 14, the same reference numerals are attached to the same configuration as the configuration illustrated in FIG. 3.

An electrode pad 116 of the first comparative example illustrated in FIG. 13 is an electrode pad made of aluminum to be connected to the first wiring pattern 15 made of aluminum and having a wiring width Ww=60 μm. The electrode pad 116 is an electrode pad having a rectangular shape with a pad length Lp=140 μm and a pad width Wp=100 μm that extends in a vertical direction with respect to the longitudinal direction of the first wiring pattern 15. Incidentally, the pad length means a length of the electrode pad 116 in the direction perpendicular with respect to the longitudinal direction of the first wiring pattern 15, and the pad width means a length of the electrode pad 116 in a direction parallel with respect to the longitudinal direction of the first wiring pattern 15. The same will be applied hereinafter.

An electrode pad 216 of the second comparative example illustrated in FIG. 14 is an electrode pad made of aluminum as similarly to the electrode pad 116 of the first comparative example, but a shape thereof is different from the electrode pad 116 of the first comparative example. The electrode pad 216 of the second comparative example is formed in a shape having a notch portion 216c with a length Lc=40 μm and a width Wc=20 μm in each of two points of a root portion to be connected to the first wiring pattern 15 in the same rectangular as the electrode pad 116 of the first comparative example.

The through hole 18 to be provided right below the different electrode pads 116 and 216 having such shapes, has an opening diameter of R=60 μm. Here, an area (area inside the dotted-line circle at the outermost circumference in FIG. 14) right above the above-described through hole 18 in the electrode pads 116 and 216 will be referred to as the through hole corresponding area, and a portion to be connected to the first wiring pattern 15 in the electrode pads 116 and 216 will be referred to as a connection end portion. The through hole 18 is provided such that a shortest distance Lwo-min of a distance Lwo between the connection end portion and the through hole corresponding area (a position Lwo of the through hole corresponding area on the electrode pad) becomes 60 μm.

With respect to the solid-state imaging device having the electrode pads 116 and 216 and the through hole 18, which are formed as above, the stress applied to the semiconductor substrate 11 around the through hole 18 due to the heat process was calculated through the simulation. Incidentally, as illustrated in FIG. 15, the respective positions of twelve points on the electrode pads 116 and 216 along the circumference of the through hole corresponding area are set to “0” to “11” in the simulation, and the stress applied to the semiconductor substrate 11 right below each of these measurement positions was calculated.

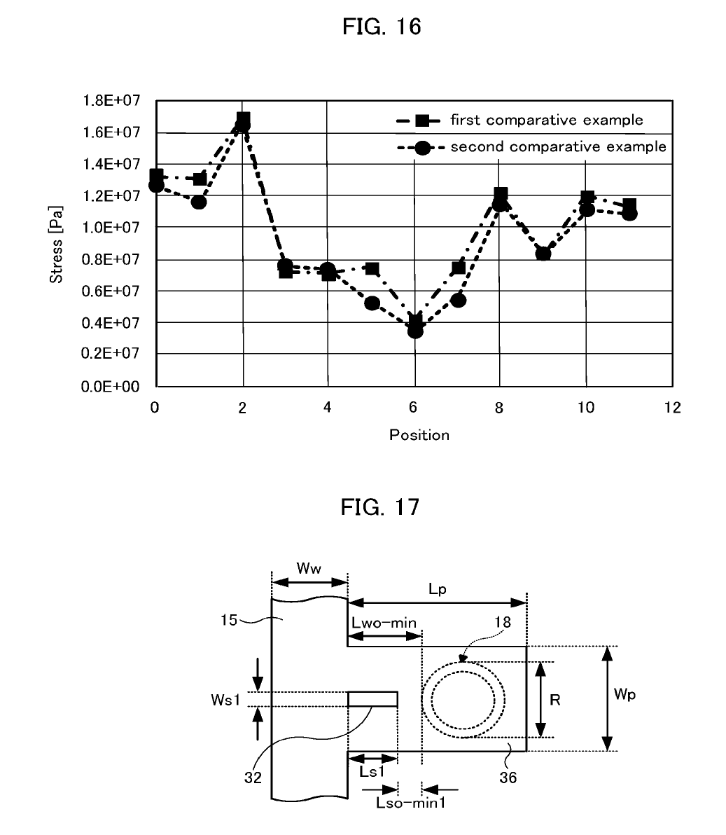

FIG. 16 is a graph illustrating a result of calculating the stress applied to the semiconductor substrate right below each of the measurement positions in a case where each of the electrode pads of the first comparative example and the second comparative example is formed. As illustrated in FIG. 16, in a case where the electrode pad 116 of the first comparative example and the electrode pad 216 of the second comparative example are formed, the stress applied to the semiconductor substrate 11 around the through hole 18 shows a tendency of being the lowest at the measurement position “6” (the measurement position farthest away from the first wiring pattern 15), and increasing as approaching the measurement position “0” (the measurement position closest from the first wiring pattern 15).

Incidentally, it was possible to further lower, although only slightly, the stress applied to the semiconductor substrate 11 around the through hole 18 overall in a case where the electrode pad 216 of the second comparative example illustrated in FIG. 14 is formed as compared to a case where the electrode pad 116 of the first comparative example illustrated in FIG. 13 is formed. Then, subsequently, each stress applied to the semiconductor substrate 11 around the through hole 18 was compared between a case where the electrode pad 216 of the second comparative example having the notch portion 216c is formed, and a case where the electrode pad 16 having the slit 22, like the electrode pad 16 according to the embodiment, is formed.

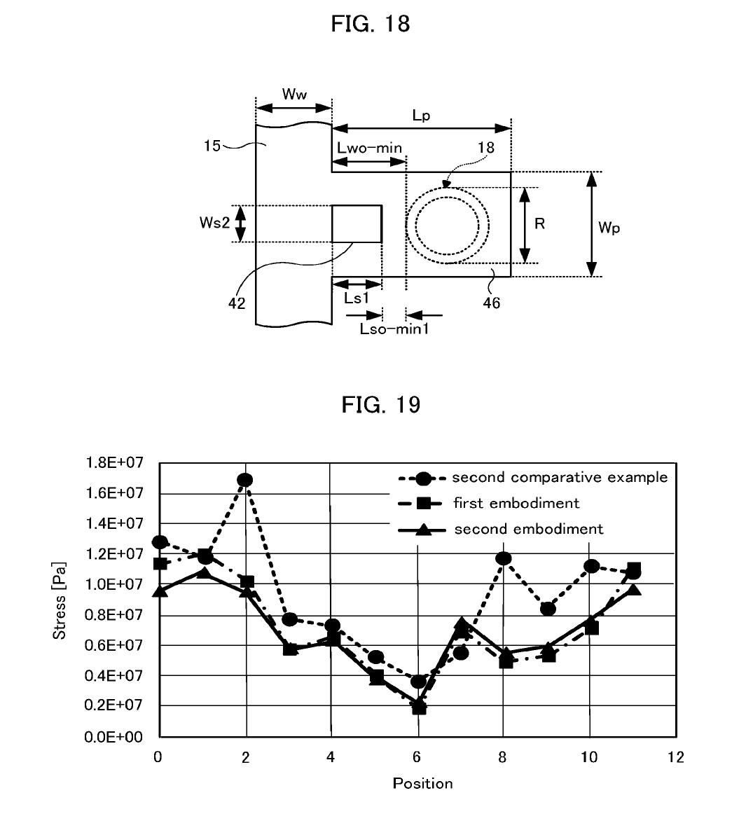

First, simulation was conducted regarding a case where the electrode pad having the slit as illustrated in each of FIG. 17 and FIG. 18 was formed. FIG. 17 is a top view illustrating an electrode pad of a first embodiment, and corresponding to FIG. 3, and FIG. 18 is a top view illustrating an electrode pad of a second embodiment and corresponding to FIG. 3. Incidentally, in each drawing of FIG. 17 and FIG. 18, the same reference numerals are attached to the same configuration as the configuration illustrated in FIG. 3.

An electrode pad 36 of the first embodiment illustrated in FIG. 17 is an electrode pad in which a slit 32 is provided in the same electrode pad as the electrode pad 116 of the first comparative example. The slit 32 has a rectangular shape having a length Ls1=40 μm and a width Ws1=10 μm, and is provided at a position that allows a shortest distance Lso−min1 of a distance Lso between the slit 32 and the through hole corresponding area (area right above the through hole 18 indicated by the dotted line at the outermost circumference in FIG. 17) to become 20 μm.

The length Ls1 of the slit 32 means a length of the slit 32 in a direction parallel to a length direction of the electrode pad 36, and the width Ws1 of the slit 32 means a length of the slit 32 in a direction parallel to a width direction of the electrode pad 36. In the same manner, hereinafter, in a case where a length of the slit is referred, it means a length of the slit in the direction parallel to the length direction of the electrode pad, and in a case where a width of the slit is referred, it means a length of the slit in the direction parallel to the width direction of the electrode pad.

An electrode pad 46 of the second embodiment illustrated in FIG. 18 is an electrode pad in which a slit 42 is provided in the same electrode pad as the electrode pad 116 of the first comparative example. The slit 42 has a square shape having the length Ls1=40 μm and a width Ws2=40 μm, and is provided at a position that allows the shortest distance Lso−min1 of the distance Lso between the slit 42 and the through hole corresponding area (area right above the through hole 18 indicated by the dotted line at the outermost circumference in FIG. 18) to become 20 μm.

With respect to the solid-state imaging device having the electrode pads 36 and 46 and the through hole 18, which are formed as above, the stress applied to the semiconductor substrate 11 around the through hole 18 due to the heat process was calculated through the simulation.

FIG. 19 is a graph illustrating a result of calculating the stress applied to the semiconductor substrate 11 right below each of the measurement positions in a case where each of the electrode pads 46 and 216 of the first embodiment, the second embodiment, and the second comparative example is formed. As illustrated in FIG. 19, even in a case where the electrode pads 36 and 46 of the first and second embodiments having the slits 32 and 42, respectively, are formed, the stress applied to the semiconductor substrate 11 around the through hole shows the tendency of being the lowest at the measurement position “6” (the measurement position farthest away from the first wiring pattern 15), and increasing as approaching the measurement position “0” (the measurement position closest from the first wiring pattern 15) as similarly to a case where the electrode pad 216 of the second comparative example without the slit is formed.

However, the result shows that it is possible to further lower the stress applied to the semiconductor substrate 11 around the through hole 18 overall in a case where the electrode pads 36 and 46 having the slits 32 and 42, respectively, as in the first and second embodiments are formed as compared to a case where the electrode pad 216 of the second comparative example is formed.

It is considered that this result is obtained because a positive stress applied to the semiconductor substrate 11 due to the heat process is canceled by a negative stress applied to the semiconductor substrate 11 around each of the slits 32 and 42 by forming each of the slits 32 and 42.

In addition, the effect of lowering the stress by providing the slits 32 and 42 is favorably obtained on a side close to the first wiring pattern 15 among a portion around the through hole 18 (the measurement positions “0” to “3” and the measurement positions “9” to “11”), and in particular, it was possible to lower the stress by about 70% at the measurement position “2”.

From this result, it is considered that it is possible to obtain the effect of lowering the stress by providing the slits 32 and 42 more favorably in a portion closer to the slits 32 and 42. From the simulation result, it is preferable that each position of the slits 32 and 42 be closer to the through hole corresponding area. To be specific, it is preferable that each of the slits 32 and 42 be provided at a position that allows the shortest distance Lso−min1 of the distance Lso between the through hole corresponding area and each of the slits 32 and 42 to become equal to or smaller than ½ of the position Lwo-min of the through hole corresponding area.

In addition, as apparent from the comparison between the first embodiment and the second embodiment, it was possible to further lower the stress in a case where each width of the slits 32 and 42 is long.

It is considered that such a result is obtained because, particularly at the measurement positions “1”, “2”, “10” and “11”, it is possible to shorten the distance Lso between each of the measurement positions and each of the slits 32 and 42 as each width of the slits 32 and 42 is longer.

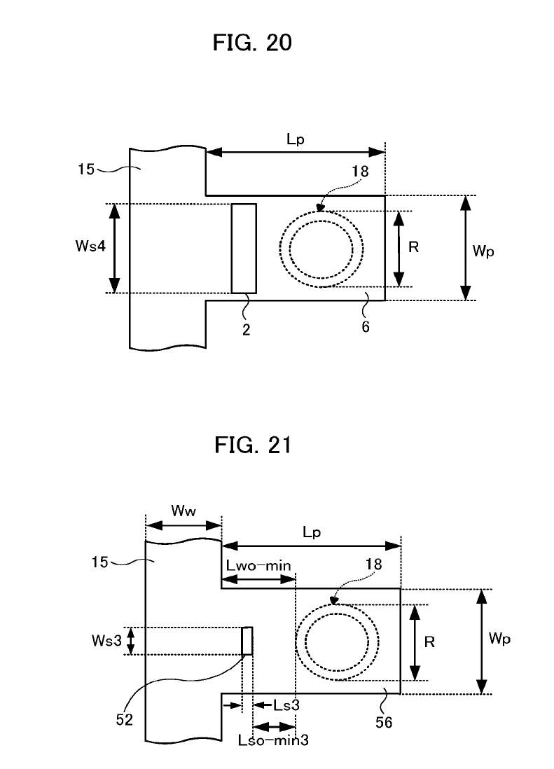

From the simulation result and study result, it is preferable that the width of the slit be long, and as illustrated in FIG. 20, it is more preferable that the slit 2 of the electrode pad 6 be provided so as to have a width Ws4 equal to or greater than the opening diameter R of the through hole 18.

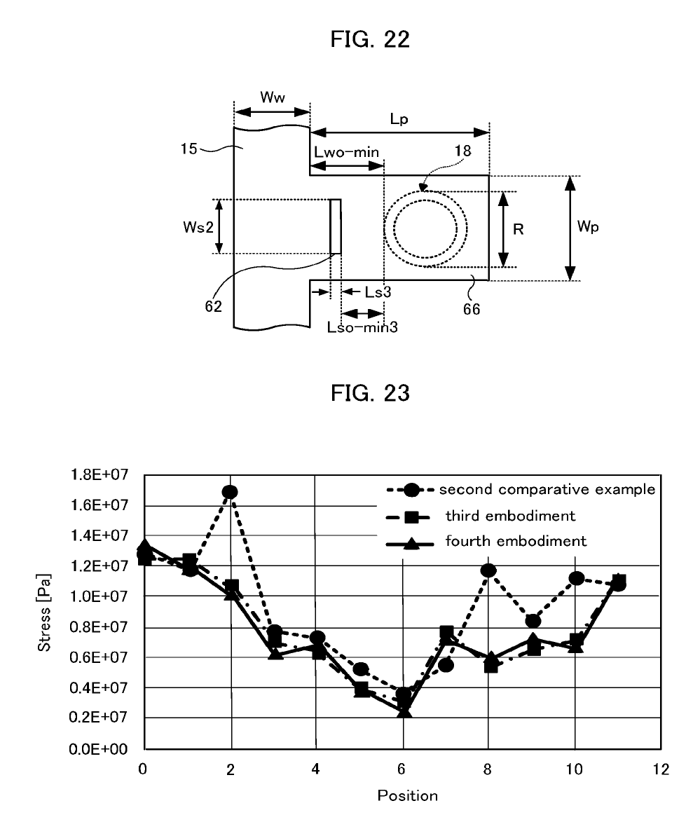

Subsequently, the simulation has been conducted regarding a case where the electrode pad having the slit as illustrated in each of FIG. 21 and FIG. 22. FIG. 21 is a top view illustrating an electrode pad of a third embodiment, and corresponding to FIG. 3, and FIG. 22 is a top view illustrating an electrode pad of a fourth embodiment, and corresponding to FIG. 3. In each drawing of FIG. 21 and FIG. 22, the same reference numerals are attached to the same configuration as the configuration illustrated in FIG. 3.

An electrode pad 56 of the third embodiment illustrated in FIG. 21 is an electrode pad in which a slit 52 is provided in the electrode pad 116 of the first comparative example. The slit 52 has a rectangular shape having a length Ls3=10 μm and a width Ws3=20 μm, and is provided at a position that allows a shortest distance Lso−min3 of the distance Lso between the slit 52 and the through hole corresponding area (area right above the through hole indicated by the dotted line at the outermost circumference in FIG. 21) to become 35 μm.

An electrode pad 66 of the fourth embodiment illustrated in FIG. 22 is an electrode pad in which a slit 62 is provided in the electrode pad 116 of the first comparative example. The slit 62 has a rectangular shape having the length Ls3=10 μm and the width Ws2=40 μm, and is provided at a position that allows the shortest distance Lso−min3 of the distance Lso between the slit 62 and the through hole corresponding area (area right above the through hole indicated by the dotted line at the outermost circumference in FIG. 22) to become 35 μm.

With respect to the solid-state imaging device having the electrode pads 56 and 66 and the through hole 18, which are formed as above, the stress applied to the semiconductor substrate 11 around the through hole 18 due to the heat process was calculated through the simulation.

FIG. 23 is a graph illustrating a result of calculating the stress applied to the semiconductor substrate 11 right below each of the measurement positions in a case where each of the electrode pads of the third embodiment, the fourth embodiment and the second comparative example is formed. As illustrated in FIG. 23, even in a case where the electrode pads 56 and 66 of the third and fourth embodiments having the slits 52 and 62, respectively, are formed, the stress applied to the semiconductor substrate 11 around the through hole 18 shows the tendency of being the lowest at the measurement position “6” (the measurement position farthest away from the first wiring pattern 15), and increasing as approaching the measurement position “0” (the measurement position closest from the first wiring pattern 15) as similarly to a case where the electrode pad 216 of the second comparative example without the slit is formed.

However, the result shows that it is possible to further lower the stress applied to the semiconductor substrate 11 around the through hole 18 overall in a case where the electrode pads 56 and 66 having the slits 52 and 62, respectively, as in the third and fourth embodiments are formed as compared to a case where the electrode pad 216 of the second comparative example is formed.

In addition, the effect of lowering the stress by providing the slits 52 and 62 is favorably obtained on a side close to the first wiring pattern 15 among the portion around the through hole 18 (the measurement positions “0” to “3” and the measurement positions “9” to “11”).

Such a tendency is the same as in a case where the electrode pads 36 and 46 having the slits 32 and 42, respectively, are formed as in the first and second embodiments.

However, as apparent from the comparison between FIG. 19 and FIG. 23, the effect of lowering the stress obtained in a case where the electrode pads 56 and 66 having the slits 52 and 62, respectively, are formed as in the third and fourth embodiments was small as compared to the effect of lowering the stress obtained in a case where the electrode pads 36 and 46 having the slits 32 and 42, respectively, are formed as in the first and second embodiments.

This is because the slits 52 and 62 of the electrode pads 56 and 66 as in the third and fourth embodiments, respectively, are provided at the positions that allow the shortest distance Lso−min between each of the slits 52 and 62 and the through hole corresponding area to be longer as compared to the slits 32 and 42 of the electrode pads 36 and 46 as in the first and second embodiments. In other words, the slits 52 and 62 of the electrode pads 56 and 66 as in the third and fourth embodiments, respectively, are formed at the positions far away from the through hole corresponding area, and thus it is hard to obtain the effect of lowering the stress applied to the semiconductor substrate 11 around the through hole 18, which is obtained by providing the slits 52 and 62 as compared to a case where the electrode pads 36 and 46 are formed as in the first and second embodiments. From such a study result, it can be stated that it is preferable that the slit be formed at a position close to the through hole corresponding area.

As apparent from the simulation results described above, it is possible to relieve the stress, which is applied to the semiconductor substrate 11 around the through hole 18 due to the heat process by the heat generated in the step of forming the second insulating film 19 (the CVD step) or the like, by providing the slits 22, 32, 42, 52 and 62 to the electrode pads 16, 36, 46, 56 and 66, respectively. As a result, it is possible to suppress the generation of the crack in the semiconductor substrate 11 around the through hole 18, and it is possible to suppress the generation of the crack in the first insulating film 14 right above the semiconductor substrate 11. Accordingly, it is possible to manufacture the thin and high-sensitive solid-state imaging device 10 as illustrated in FIG. 1A with the high yield.

### Modified Example

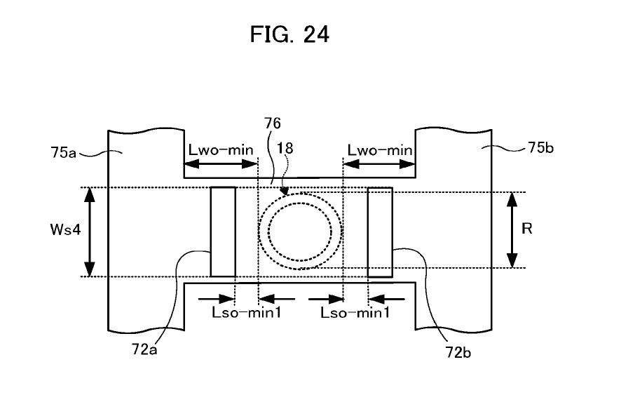

FIG. 24 is a top view illustrating an electrode pad according to a modified example of the embodiment, and corresponding to FIG. 3. In FIG. 24, the same reference numerals are attached to the same configuration as the configuration illustrated in FIG. 3. As illustrated in FIG. 24, in a case where an electrode pad 76 is provided between a plurality of first wiring patterns 75a and 75b, provided on the semiconductor substrate 11, so as to be in contact with the first wiring patterns 75a and 75b, it is possible to obtain the same effect as in the embodiment described above by providing a first slit 72a between the first wiring pattern 75a on one side and the through hole corresponding area, and a second slit 72b between the first wiring pattern 75b on the other side and the through hole corresponding area.

Incidentally, each of the first slit 72a and the second slit 72b may have any shape among the shapes of the slit 2, 22, 32, 42, 52 and 62 described above. However, as illustrated in FIG. 24, it is preferable that the first slit 72a be provided at a position that allows the shortest distance Lso−min1 of the distance Lso between the through hole corresponding area and the first slit 72a to become equal to or smaller than ½ of the position Lwo-min of the through hole corresponding area. In the same manner, it is preferable that the second slit 72b be provided at a position that allows the shortest distance Lso−min1 of the distance Lso between the through hole corresponding area and the second slit 72b to become equal to or smaller than ½ of the position Lwo-min of the through hole corresponding area.

In addition, as illustrated in FIG. 24, it is preferable that the first slit 72a be provided so as to have the width Ws4 equal to or greater than the opening diameter R of the through hole 18. In the same manner, it is preferable that the second slit 72b be provided so as to have the width Ws4 equal to or greater than the opening diameter R of the through hole 18.

Further, it is preferable that the first and second slits 72a and 72b have shapes symmetrical to each other with the through hole corresponding area as a center thereof, and be formed at symmetrical positions with the through hole corresponding area as a center thereof.

In addition, although not illustrated, each slit of the present embodiment is formed in a rectangular shape and a square shape, but it is possible to obtain the same effect with a polygonal shape or a circular shape.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a semiconductor substrate having a top surface on which a light receiving section that receives light is provided, the semiconductor substrate having a through hole which is provided in a part of the semiconductor substrate;
a first wiring provided on the top surface side of the semiconductor substrate;
an electrode pad provided on the top surface side of the semiconductor substrate including an area right above the through hole to be in contact with the first wiring, the electrode pad having a slit between the area right above the through hole and the first wiring;
an insulating film provided on a side surface of the through hole; and
a second wiring provided on the insulating film to be in contact with the electrode pad.

2. The solid-state imaging device according to claim 1,
wherein a width of the slit is equal to or greater than an opening diameter of the through hole.

3. The solid-state imaging device according to claim 1,
wherein the slit is provided at a position that allows a distance between the slit and the area right above the through hole to become equal to or smaller than ½ of a distance between the area right above the through hole and the first wiring.

4. The solid-state imaging device according to claim 3,
wherein the slit has a rectangular shape, and the area right above the through hole has a circular shape, and
the slit is provided at a position that allows a shortest distance between the slit and the area right above the through hole to become equal to or smaller than ½ of a shortest distance between the area right above the through hole and the first wiring.

5. The solid-state imaging device according to claim 1,
wherein a plurality of the first wirings is provided,
the electrode pad is provided between the plurality of first wirings to be in contact with the first wirings, and
a plurality of the slits is configured of a first slit provided between the area right above the through hole and one of the first wirings, and a second slit provided between the area right above the through hole and another one of the first wirings.

6. The solid-state imaging device according to claim 5,
wherein each of a width of the first slit and a width of the second slit is equal to or greater than an opening diameter of the through hole.

7. The solid-state imaging device according to claim 5,
wherein the first slit is provided at a position that allows a distance between the first slit and the area right above the through hole to become equal to or smaller than ½ of a distance between the area right above the through hole and the one first wiring, and
the second slit is provided at a position that allows a distance between the second slit and the area right above the through hole to become equal to or smaller than ½ of a distance between the area right above the through hole and the another first wiring.

8. The solid-state imaging device according to claim 7,
wherein each of the first and second slits has a rectangular shape and the area right above the through hole has a circular shape,
the first slit is provided at a position that allows a shortest distance between the first slit and the area right above the through hole to become equal to or smaller than ½ of a shortest distance between the area right above the through hole and the one first wiring, and
the second slit is provided at a position that allows a shortest distance between the second slit and the area right above the through hole to become equal to or smaller than ½ of a shortest distance between the area right above the through hole and the another first wiring.

9. A camera module comprising:
a solid-state imaging device; and
a lens holder having a lens, the lens being included inside the lens holder,
wherein the solid-state imaging device including:
a semiconductor substrate having a top surface on which a light receiving section that receives light condensed by the lens is provided, the semiconductor substrate having a through hole which is provided in a part of the semiconductor substrate;
a first wiring provided on the top surface side of the semiconductor substrate;
an electrode pad provided on the top surface side of the semiconductor substrate including an area right above the through hole to be in contact with the first wiring, the electrode pad having a slit between the area right above the through hole and the first wiring;
an insulating film provided on a side surface of the through hole; and
a second wiring provided on the insulating film to be in contact with the electrode pad, and
wherein the lens holder is provided on the top surface of the semiconductor substrate.

10. The camera module according to claim 9,
wherein the solid-state imaging device is not provided with a glass substrate.

11. The camera module according to claim 10,
wherein the light receiving section directly receives the light without intervention of the glass substrate.

12. A semiconductor device comprising:
a first wiring provided on a top surface side of a semiconductor substrate having a through hole;
an electrode pad provided on the top surface side of the semiconductor substrate including an area right above the through hole to be in contact with the first wiring, the electrode pad having a slit between the area right above the through hole and the first wiring;
an insulating film provided on a side surface of the through hole; and
a second wiring provided on the insulating film to be in contact with the electrode pad.

13. The semiconductor device according to claim 12,
wherein a width of the slit is equal to or greater than an opening diameter of the through hole.

14. The semiconductor device according to claim 12,
wherein the slit is provided at a position that allows a distance between the slit and the area right above the through hole to become equal to or smaller than ½ of a distance between the area right above the through hole and the first wiring.

15. The semiconductor device according to claim 14,
wherein the slit has a rectangular shape, and the area right above the through hole has a circular shape, and
the slit is provided at a position that allows a shortest distance between the slit and the area right above the through hole to become equal to or smaller than ½ of a shortest distance between the area right above the through hole and the first wiring.

16. The semiconductor device according to claim 12,
wherein a plurality of the first wirings is provided,
the electrode pad is provided between the plurality of first wirings to be in contact with the first wirings, and
a plurality of the slits is configured of a first slit provided between the area right above the through hole and one of the first wirings, and a second slit provided between the area right above the through hole and another one of the first wirings.

17. The semiconductor device according to claim 16,
wherein each of a width of the first slit and a width of the second slit is equal to or greater than an opening diameter of the through hole.

18. The semiconductor device according to claim 16,
wherein the first slit is provided at a position that allows a distance between the first slit and the area right above the through hole to become equal to or smaller than ½ of a distance between the area right above the through hole and the one first wiring, and
the second slit is provided at a position that allows a distance between the second slit and the area right above the through hole to become equal to or smaller than ½ of a distance between the area right above the through hole and the another first wiring.

19. The semiconductor device according to claim 18,
wherein each of the first and second slits has a rectangular shape and the area right above the through hole has a circular shape,
the first slit is provided at a position that allows a shortest distance between the first slit and the area right above the through hole to become equal to or smaller than ½ of a shortest distance between the area right above the through hole and the one first wiring, and
the second slit is provided at a position that allows a shortest distance between the second slit and the area right above the through hole to become equal to or smaller than ½ of a shortest distance between the area right above the through hole and the another first wiring.
